(19) United States
(12) Patent Application Publication
(10) Pub. No.: US 2012/0132251 A1
(43) Pub. Date: May 31, 2012

(54) SOLAR CELL, SOLAR MODULE COMPRISING SAID SOLAR CELL AND METHOD FOR PRODUCING THE SAME AND FOR PRODUCING A CONTACT FOIL

(75) Inventors: Michael Sedlacek, Hamburg (DE); Joerg Mueller, Sandersdorft (DE); Claudio Meisser, Cham (CH)

(73) Assignee: Komax Holding AG, Dierikon (CH)

(21) Appl. No.: 13/318,752

(22) PCT Filed: May 3, 2010
(86) PCT No.: PCT/EP2010/055991

§ 371 Date: Jan. 23, 2012

(30) Foreign Application Priority Data
May 5, 2009 (DE) 102009002823.4

(51) Int. Cl. H01L 31/0224; H01L 31/05; H01L 31/18

(52) U.S. Cl. 136/244; 438/98; 136/256; 257/E31.124

(57) ABSTRACT

The invention relates to a solar cell which comprises the following layers: (a) a semi-conducting layer comprising a first surface and a second surface, wherein on the first surface a plurality of first contact points and second contact points are formed, which have opposing polarities; (b) a first single- or multi-layered, perforated foil, made of an electrically non-conductive material, which has a plurality of first holes; and (c) a structured electrically conductive layer on a surface of the perforated foil facing away from the semi-conducting layer; wherein the perforated foil and the semi-conducting layer are positioned to each other such that at least a part of the first holes and of the first contact points and of the second contact points are located opposite of each other, wherein at least a part of the first contact points and of the second contact points are connected by way of a solderless electrically conductive connection to the structured electrically conductive layer. The invention further relates to a solar module which comprises a plurality of said solar cells, to a method for producing the solar cell, and to a method for producing a contact foil.

### CROSS-REFERENCE TO RELATED APPLICATIONS

This application is a national stage application under 35 U.S.C. §371 of PCT Application No. PCT/EP2010/055991, filed May 3, 2010, which claims priority to and the benefit of German patent application no. 102009002823.4, filed May 5, 2009, which is incorporated herein by reference in its entirety.

### TECHNICAL FIELD

The invention relates to a solar cell, a solar module comprising said solar cell, further a method for the production of said solar cell and a method for the production of a contact foil.

### BACKGROUND OF THE INVENTION

Conventional solar cells consist of a layered structure which is formed in a panel-shaped semiconductor material, for example, consisting of mono- or polycrystalline silicon. The semiconductor provides the p-type base material. Through the diffusion of phosphorus into the material, a thin n-type layer—the so-called emitter—is produced on the surface. Commonly, contact is provided with the base using an aluminium layer applied to the entire area. The emitter is contacted via narrow fingers, which are connected to each other using one or several so-called bus bars. The metallic fingers and bus bars prevent light from entering the contact areas of the solar cells, however, too few fingers or fingers that are too narrow increase serial resistance; therefore, fingers and bus bars must be constructed in such a way as to minimise electric power losses and shading losses. The spatial separation of emitter contact (front surface, directed towards the solar radiation) and base contact (rear surface), however, renders connecting solar cells to modules more difficult as front and back contact of two neighbouring solar cells have to be soldered together in a complex process. Conventional solar cells possess contact points on the front and rear surface, which are usually connected using tape-like conductors, whereas solar cells with rear contacts allow simplified interconnection concepts.

In order to increase efficiency, so-called rear contact solar cells have been developed. In such rear contact solar cells, the front side emitter is electrically connected to a back side emitter contact. In this manner, shading losses caused by metallic conducting tracks on the front face can be minimised.

WO 2007/096752 A2 discloses a method for providing contact in rear contact solar cells in which connection is provided through holes in a perforated, electrically insulating foil attached to the solar cell by way of wave soldering. Such method carries the disadvantage of a comparatively high temperature strain on the solar cell as well as the utilisation of a solder, which first has to be melted.

### SUMMARY OF THE INVENTION

The underlying problem of the present invention is to provide a solar cell of the rear contact solar cell type as well as a corresponding solar module containing a plurality of rear contact solar cells, in which solar module a simple and inexpensive way for providing contact to and electrically connecting solar cells is achieved. A further purpose of the invention is to provide a method to produce said solar cell.

The solution to this problem is obtained according to the invention by a solar cell with the properties of the according independent claim, the solar module of the according independent claim as well as the method for the production of the solar cell of the according independent claim. In conclusion, the solution to this problem is obtained through a method to produce a contact foil, which method is particularly suited for the production of the solar cell according to the invention. Preferred embodiments of the solar cell according to the invention are disclosed in the corresponding dependent claims. Preferred embodiments of the solar cell according to the invention correspond to preferred embodiments of the solar module according to the invention and vice versa, without necessarily being explicitly stated herein. This shall be applied by analogy to the materials, foils and layers utilised in the solar cell according to the invention and in the methods according to the invention.

### BRIEF DESCRIPTION OF THE DRAWINGS

FIG. 1 shows a section of the solar module 3, which comprises several solar cells 1 according to the present invention in a linear arrangement.

FIG. 2 shows an enlarged section of the solar module shown in FIG. 1 according to the present invention.

FIG. 3 shows in a perspective view of a section of a solar cell three adjacently arranged variants—according to the invention—of electrically conductive connections between the electrically semiconducting layer and the structured electrically conductive layer.

FIG. 4 shows a cross-section through a solar cell according to one embodiment of the present invention.

FIG. 5 shows a cross-section through a solar cell according to another embodiment of the present invention.

FIG. 6 shows a perspective view of a first embodiment of a method—according to the invention—to produce a contact foil.

FIG. 7 shows a perspective view of a second embodiment of a method—according to the invention—to produce a contact foil.

FIG. 8 shows a typical connection variant in a solar module.

### DETAILED DESCRIPTION OF THE INVENTION

The subject matter of the present invention concerns a solar cell which comprises the following layers:
(a) a semiconducting layer with a first surface and a second surface, wherein on the first surface there are a plurality of first contact points and second contact points, which show opposing polarity;
(b) a first single layer or multilayer perforated foil, consisting of an electrically non-conductive material, said foil containing a plurality of first holes
(c) a structured electrically conductive layer on a surface of the perforated foil, which surface is facing away from the semiconducting layer
   wherein the perforated foil and the semiconducting layer are positioned in such a way that at least a part of the first holes and the first contact points and the second contact points are facing each other, and wherein at least a part of the first contact points and the second contact points are joined to the structured electrically conductive layer via a solder-free electrically conductive connection.

“Solder-free electrically conductive connection” generally means that the electrically conductive connection contains no material (solder), which has a lower melting point than the parts to be connected.

To this end, in the semiconducting layer such materials can be used as are known to the person skilled in the art.

The electrically conductive layer can consist of a wide range of electrically conductive materials, as long as these materials do not impede the function of the electrically conductive layer in a solar cell. The electrically conductive layer can, in particular, consist of a metal or an electrically conductive organic polymer.

As metals for the electrically conductive layer, noble metals, aluminium and aluminium alloys, copper, titanium or silver are used preferentially. Particularly preferred is the use of aluminium, aluminium alloys and copper, and especially preferred is the use of aluminium or aluminium alloys. Identical metals as well as differing metals can be joined to each other. A multi-layered assembly (for example Al/Cu) is possible as well.

Electrically conductive organic polymers are particularly suited if they possess chains with conjugated double bonds. Amongst these polymers, such are preferred, which are derived from a substituted polythiophene, wherein the substituents preferably comprise C1-C10-alkyl- or alkoxy groups.

Ultrasonic welding is particularly suited to join the aforementioned metals. Utilising ultrasonic welding, a connection of electrically conductive thermoplastic synthetic materials with each other or with a metal can be obtained.

Preferentially, the electrically conductive layer possesses a thickness between 0.05 and 0.2 mm and is in particular an aluminium or copper foil.

The term “single layer or multilayer foil” used herein is to be interpreted broadly; it comprises a single foil from a certain material, for example a polyethylene terephthalate (PET) foil, but also a laminate, which consists of several joined foils. Hence, the term “layer” used herein can have the meaning of foil.

In case that as a first single layer or multilayer perforated foil, a single layer foil is perforated by punching yielding a plurality of first holes and the resulting perforated foil is laminated with an electrically conductive layer, a polyethylene terephthalate foil is used by preference. Such a single layer foil is referred to herein as an insulating foil.

In case that as a first single layer or multilayer perforated foil, a multilayer foil is used, the materials EVA (ethylene-vinyl acetate)-polymer and polyethylene phthalate are used preferentially. One of said layers or foils is referred to herein as insulating foil as well; this insulating foil is preferentially a polyethylene terephthalate foil.

The first single layer or multilayer perforated foil from a non-conductive material can contain a rear foil as a rear coating to protect the solar cell or the solar cell contained in a solar module, respectively, from environmental stress. The rear coating preferentially contains a fluorine containing polymer, particularly preferred is polyvinyl fluoride (PVF). A particularly suitable polyvinyl fluoride is obtainable under the name of Tedlar® from Dupont. The rear coating can be single layer or multilayer, for example a PVF-polyester-PVF composite.

The use of a multilayer foil as the first single layer or multilayer foil is preferred according to the invention, as when a preferentially soft insulating foil is used (also referred to as a fusible layer), the process of punching is simplified. An EVA foil is soft and is therefore preferentially punched in conjunction with a supporting second foil.

The foils or layers, which are used in the first single layer or multilayer foil have a preferred thickness of from 0.01 to 0.5 mm, especially preferred is 0.2 to 0.4 mm.

The first single layer or multilayer foil is generally joined to an electrically conductive layer using an adhesive. Such adhesives are known.

In a preferred embodiment of the solar cell according to the invention, the solder-free electrically conductive connection comprises a contact tape between the part of the first and second contact points and the structured electrically conductive layer.

The material of the contact tape is generally chosen from the same materials as that of the electrically conductive layer. The size of the contact tape is preferentially adapted to the size of the first and a second hole described below, which preferentially display a diameter from 1 to 10 mm, particularly preferred from 2 to 5 mm. In this, generally, the distance between the holes is accounted for in that for a greater distance between the holes, usually a larger contact tape can be used.

Furthermore, it is preferred that the solder-free electrically conductive connection comprises an electrically conductive adhesive or that such connection is obtainable by ultrasonic welding.

The electrically conductive connection can preferentially be obtained by laser beam welding. In this, a restrainer for the electrically conductive layer is used, so the electrically conductive layer and the contact points can have contact. In the position, in which the laser beam passes the restrainer, the restrainer is generally transparent or the restrainer contains an opening in such place.

Generally, the solar cell according to the invention contains further layers in addition to the layers already mentioned (semiconducting layer, first single layer or multilayer perforated foil, structure electrically conductive layer). In this respect the solar cell according to the invention contains preferentially on the second surface of the semiconducting layer a second single layer or multilayer foil, which comprises, for example, an anti-reflective layer (for example silicon nitride) and/or another protective foil (for example ethylene-vinyl acetate polymer). Finally, in general, on the second single layer or multilayer foil there is a transparent pane of, for example, glass or polycarbonate, preferentially from glass.

The thickness of the semiconducting layer is preferentially from 20 to 500 μm and especially preferentially from 80 to 220 μm. The thickness of the first single layer or multilayer perforated foil is preferentially from 20 to 400 μm. The thickness of the structured electrically conductive layer is preferentially from 5 to 200 μm.

Especially preferred according to the invention the solder-free electric connection is obtainable by ultrasonic welding.

Ultrasonic welding, with or without simultaneous supply of thermal energy, is a form of welding, in which the kinetic energy in the form of friction is used, which is generally created through an oscillating translational relative movement of the parts to be connected under the influence of static pressure. In comparison, in friction welding, friction is used, which is created predominantly through a rotating or oscillating relative movement of the parts to be connected under the influence of static pressure. Whilst, according to the invention, friction welding can be used in principle for the creation of the electrically conductive connection as well, ultrasonic welding is particularly preferred.

Generally, an ultrasonic welding device contains a lower electrode (referred to as “anvil”) and an upper electrode (referred to as “sonotrode”). The sonotrode executes oscillations in a connecting plane of surfaces to be joined at a frequency generally between 10 and 200 kHz, preferably between 30 and 100 kHz. The amplitude is generally between 1 and 50 μm and the power is generally between 0.01 and 1 kW, wherein then welding times are generally between 0.1 and 1 sec. The direction of the oscillations of the ultrasound and the direction of the force are generally perpendicular to each other, wherein the surfaces to be connected are rubbing on each other. Preferentially, the use of welding additives is dispensed with.

According to the invention it is preferred that the ultrasonic welding is carried out without the supply of additional thermal energy. However, the ultrasonic welding can also be performed while supplying additional thermal energy, for example, by the additional heating of the anvil.

For the concentrated introduction of ultrasonic energy, sonotrode and anvil can be adapted to the according connection type.

The achievable durability of the electrically conductive connection depends on several parameters. In particular the kind of materials to be welded, the welding power and welding amplitude of the welding system and the properties of sonotrode and anvil are to be considered. Numerous and diverse materials can be used as materials for the sonotrode and the anvil as long as the purpose of the invention can be achieved.

For the concentrated introduction of ultrasonic energy, sonotrode and anvil can be adapted to the according shape of the desired electrically conducting connection.

Herein, it can be considered, whether the materials to be connected have to be made to come into physical contact with each other first. In this way, in an particularly preferred embodiment of the invention, the structured electrically conductive layer is pressed onto the first contact points and the second contact points of the semiconducting layer with the aid of an ultrasonic welding device.

In a preferred embodiment of the solar cell according to the invention, the solder-free electrical connection is a direct connection between the first and second contact points or a part of which and the structured electrically conductive layer. “Direct connection” carries the particular meaning that between the first and the second contact point of the structured electrically conductive layer there is no further material. The direct connection can preferably be produced by ultrasonic welding.

Another subject matter of the invention is a solar module, which possesses a plurality of the solar cells described above. The solar cells are generally situated next to each other and are electrically connected to each other. On the rear surface, that is, on the surface of the solar cell facing away from the solar radiation during operation, there are arranged at a distance to each other, in a predetermined arrangement, for example, in a matrix arrangement, a plurality of first contact points with a first polarity and of second contact points with an opposing polarity. In this, the contact sections of opposing polarity are nested within each other, in accordance with the layout of the corresponding contact points to be contacted.

Preferentially, the contact points of identical polarity are arranged on the rear side of the solar cells alternatingly per polarity in parallel rows. A contact foil from the first single layer or multilayer, perforated foil and the structured electrically conductive layer can cover a single row of solar cells (so-called string) or an entire solar module.

Furthermore, electrically connecting media are designated to connect neighbouring solar cells to each other.

In particular, through the etching off of an area of the electrically conductive layer, for example a metal foil consisting of aluminium or copper, conductive traces are formed, which connect the solar cells in the desired fashion after the preferred ultrasonic welding, for example in a series connection to yield a higher voltage or in a parallel connection to yield a higher amperage of the electric current generated by the solar cell when exposed to light. Combinations of the two circuits are also possible.

Suitable connection arrangements for the electric connection of solar cells are disclosed in WO 2008/113741 A, for example.

Finally, the subject matter of the invention is a method to produce a solar cell which comprises the following layers:
(a) a semiconducting layer with a first surface and a second surface, wherein on the first surface there are a plurality of first contact points and second contact points, which show opposing polarity;
(b) a first single layer or multilayer, perforated foil, consisting of an electrically non-conductive material, said foil containing a plurality of first holes;
(c) a structured electrically conductive layer on the surface of the perforated foil, which surface is facing away from the semiconducting layer;
wherein the first single layer or multilayer perforated foil and the semiconducting layer are positioned in such a way that at least a part of the first holes and the first contact points and the second contact points are facing each other and wherein at least one part of the first and the second contact points are joined to the structured electrically conductive layer via a solder-free electrically conductive connection, and wherein
(d) a first single layer or multilayer perforated foil, consisting of an electrically non-conductive material, said foil containing a plurality of first holes, is applied on a semiconducting layer, and an electrically conductive layer is applied to said perforated foil, wherein the perforated foil is applied on the semiconducting layer in such a way that at least a part of the first holes and the first contact points and the second contact points are facing each other;
(e) the electrically conductive layer undergoes structuring; and
(f) the structured electrically conductive layer thereby generated, is joined through the first holes to the first contact points and the second contact points via a solder-less electrically conducting connection.

“Structuring of the electrically conductive layer” means that parts are removed from an originally compact electrically conductive layer in such way that only parts of the originally compact electrically conductive layer remain which are relevant for a designated contacting of contact points. This can be achieved, for example, in that a covering layer is applied to the electrically conductive layer in such way that only the structures of the structured electrically conductive layer later yielded are masked by the covering layer. The parts of the electrically conductive layer not masked by the covering layer can then be removed in a suitable etching bath, for example.

Preferably, the structured electrically conductive layer is joined to the first contact points and the second contact points by ultrasonic welding or friction welding, particularly preferably by ultrasonic welding.

In a preferred embodiment of the invention, a first single layer or multilayer foil consisting of one or several electrically non-conductive materials is perforated by way of punching, thus yielding a plurality of first holes and the thereby generated first single layer or multilayer perforated foil is laminated to an electrically conductive layer.

In an particularly preferred embodiment of the method according to the invention the structured electrically conductive layer is pressed through the first holes onto the first contact points and the second contact points and subsequently the structured electrically conductive layer is joined to the first contact points and the second contact points by ultrasonic welding. In this, the pressing of the structured electrically conductive layer onto the first contact points and the second contact points is carried out preferably by using an ultrasonic welding device. To this end, the sonotrode can be designed at the tip in such a way as to ensure an optimal pressing.

The first holes preferentially take a round shape. During the pressing down of the structured electrically conductive layer, generally, a circular section of the electrically conductive layer is pressed down. In order to decrease mechanical tension it can be provided that before pressing down, a circular section is cut out on each side of a remaining bridge.

In an alternative embodiment of the method according to the invention, the electrically conductive layer is provided with a plurality of second holes by punching in such way that the second holes are positioned on top of the first holes; a contact tape is applied between the part of the first contact points and the second contact points and the structured electrically conductive layer; and a solder-free electrically conductive connection is produced.

The first and/or second holes can have different cross-sections. By preference, both the first holes as well as the second holes have a circular cross-section.

The size of the first holes and/or second holes generally corresponds to a circle with a diameter between 1 and 10 mm, preferably between 2 and 5 mm, wherein the first holes and the second holes preferably have the same cross-section.

According to the invention the distance between the holes (first and second holes) and/or between the contact points preferably amounts to between 1 and 15 cm and particularly preferably between 3 and 7 cm.

In the solar cells according to the present invention as well as in the method for the production of said solar cells according to the invention, the production of second holes, preferably by punching of the electrically conductive layer thus yielding second holes in the electrically conductive layer, can be performed before or after the structuring of the metallically conductive layer, for example, in an etching bath.

The contact tape is applied on top of the second holes and by pressing down is brought into physical contact with the semiconducting layer. Herein, the physical contact can be direct or indirect. In an indirect contact there is—for example—a electrically conductive adhesive, which is known per se, between the contact band and the semiconducting layer and/or the electrically conductive layer. The contact tape is joined in generally two places to the structured electrically conductive layer and in one place to the semiconducting layer. In these three places an electrically conductive connection can be carried out using different methods such as for example adhesive bonding or ultrasonic welding. It is however preferable that the same kind of connection be used in all three places, such that, for example, the contact tape is joined to the electrically conductive layer in two places by ultrasonic welding and in one place to the semiconducting layer.

The adhesive, which may be electrically conducting, can be applied to the cells or the contact foil by dispensing or screen printing. The said adhesive can be a single component or multiple component adhesive, which bonds at room temperature, increased temperature, under pressure or UV radiation.

The invention also concerns a method for the production of a contact foil, which comprises a structured electrically conductive layer and a first single layer or multilayer, perforated foil consisting of an electrically non-conductive material with a plurality of first holes, wherein
(g) a first single layer or multilayer foil consisting of one or several electrically non-conductive materials is provided;
(h) a first single layer or multilayer foil is joined to an electrically conductive layer;
(i) a covering layer is applied to at least one portion of the electrically conductive layer;
(j) the parts of the electrically conductive layer not provided with the covering layer are removed in an etching bath; and
(k) a plurality of first holes is created in at least the first single layer or multilayer foil by way of punching;
wherein the punching according to step (k) can be performed after each or any of the steps (g) to (j).

A contact foil in the sense of the present invention is a foil with at least two layers, in which foil one layer consists of an electrically conductive material and another layer consist of an electrically insulating material.

In general, the covering layer is only applied after the first single layer or multilayer foil has been joined to an electrically conductive layer.

The application of a covering layer is performed preferably by applying a coating paint for the protection of the parts of the electrically conducting layer, which parts are not to be etched off in the etching bath. The coating paint can be applied using different methods, for example by spraying, squirting or screen printing. In the particular case that the coating paint is applied over the entire area, the method for the application of the coating paint is not especially limited. Should specific structures be protected before the etching process, however, the coating paint is preferentially applied by screen printing.

The etching bath consists of chemical substances, which enable the etching off of the non-protected parts of the electrically conductive layer. The composition depends on the kind of metal or electrically conductive polymers used.

Subsequent to the etching step (j) in the etching bath, a cleaning of the contact foil can be performed in another bath (immersion bath), for example. The punching of the foil can be performed between the etching step and the cleaning of the yielded contact foil or after the cleaning of the laminate consisting of structured electric layer and first single layer or multilayer foil after the passage through the etching bath. A cleaning step after the etching bath can particularly concern itself with a removal of the covering layer (for example coating paint) from the protected areas and/or from the components of the etching bath.

In the method for the production of a contact foil according to the invention, preferably a first single layer or multilayer foil is used, which comprises a double-sided self-adhesive insulating foil, on one side of which a second single layer or multilayer foil is positioned, for example, a rear foil, and on the other side of which a separating foil is applied, for example a siloxane liner. In this, it is preferred that the first single layer or multilayer foil is provided with an adhesive on the surface to be joined to the electrically conducting layer.

When using a second single layer or multilayer foil, the punching of the insulating foil is simplified, in particular, if the first single layer or multilayer foil exclusively consists of an insulating foil.

The present invention allows for solar cells to be equipped in an efficient way with a very good electrically conductive connection between the layer used for the production of electric current, that is the semiconducting layer, and the electrical connection used to conduct away the solar electric current produced.

Additionally, the present invention makes it possible that rear contact solar cells can be electrically connected in an optimal manner with a flexible printed circuit (contact foil) and at the same time can be correctly fixed and positioned to each other.

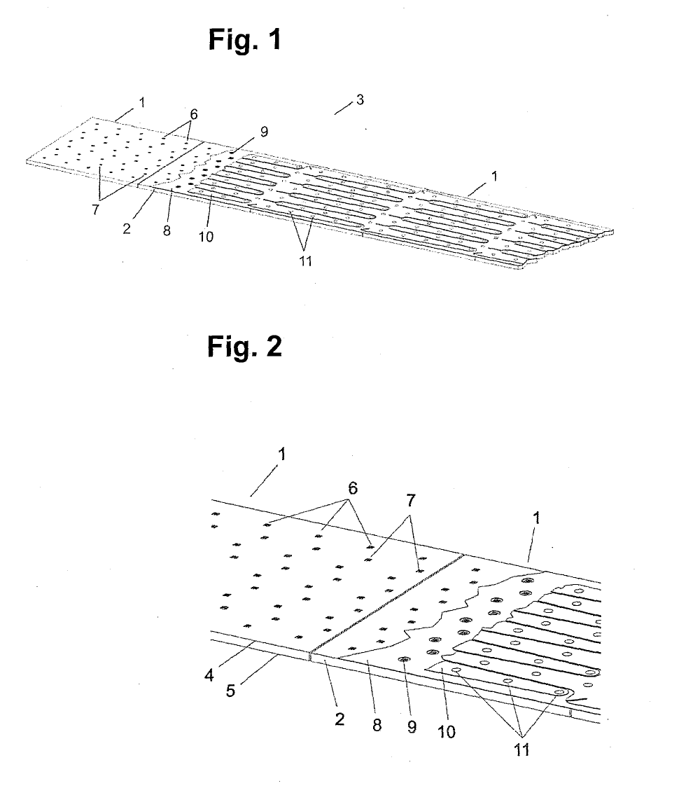

Further details of the invention are disclosed in the following description of non-limiting implementation examples for the solar cell according to the invention and the methods according to the invention. In this, FIGS. 1-7 are referenced.

FIG. 1 shows a section of a solar module 3, which comprises several solar cells 1 in a linear arrangement, wherein the complexity of the layered composition shown increases from left to right.

On top of a semiconducting layer 2 with first contact points 6 with positive polarity and second contact points 7 with negative polarity is arranged a perforated foil 8 consisting of an electrically non-conductive material with first holes 9. On top of the perforated foil 8 is arranged a structured electrically conductive layer 10, which is connected in an electrically conducting way to the first and second contact points 6,7 of the semiconducting layer 2 via solder-free electric connections 11. The first and second contact points 6,7 of the semiconducting layer 2 are therefore facing the first holes 9 and the perforated foil 8.

FIG. 2 shows an increased section of the solar module according to the present invention shown in FIG. 1, in which 2 interconnected solar cells 1 are partially visible.

A semiconducting layer 2 displays a first surface 4, which during operation of the solar cell is facing away from the solar radiation, and a second surface 5, which during operation of the solar module is facing the solar radiation. The first surface 4 of the semiconducting layer 2 displays first contact points 6 with positive polarity and second contact points 7 with negative polarity. On the first surface 4 there is a perforated foil 8 consisting of an electrically non-conductive material with first holes 9 arranged in such way that the first holes 9 are positioned on top of the first and second contact points 6,7. On top of the perforated foil 8 a structured electrically conductive layer 10 is positioned, which is connected electrically conductive with the first and second contact points 6,7 of the semiconducting layer 2 via solder-free electric connections 11. The first contact points 6 and the second contact points 7 are arranged in alternating rows, in order to ensure an optimal conduction of the electricity produced in connection with an according structured electrically conductive layer 10.

The size of the first holes 9 in the embodiment of the invention shown in FIGS. 1 and 2 is each 4 mm, wherein the distance between the first holes 9 is 6 cm in the embodiment shown here. Other distances and sizes are possible.

In the solar cells shown in FIGS. 1 and 2, crystalline silicon is used as a material for the semiconducting layer.

The solar cells contained in the solar modules shown in FIGS. 1 and 2 are connected to each other in series in a way, which is not shown in detail.

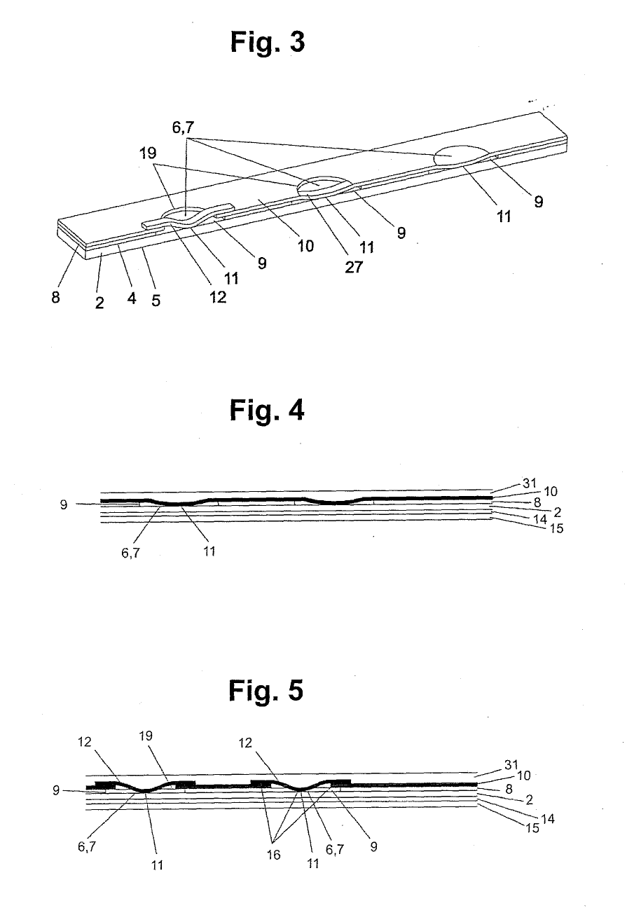

FIG. 3 shows in a perspective view of a section of a solar cell three adjacently arranged variants—according to the invention—for electrically conductive connections 11 between the electrically semiconducting layer 2 and the structured electrically conductive layer 10 through a perforated foil 8. In practice, however, generally only one of these variants is used on a solar cell or solar module, respectively. All variants have in common that on a semiconducting layer 2 with a first surface 4 and a second surface 5 there are first and second contact points 6, 7 of differing polarity arranged on the first surface 4. As the type of polarity has no effect on the electric connection, this polarity is not shown here.

In the first variant shown in FIG. 3 on the left, an electrically conductive connection 11 is achieved in that a contact tape 12 positioned on a structured electrically conductive layer 10 is electrically connected through a first hole 9 in the perforated foil 8 and a second hole 19 in the structured electric layer 10 with a first or second contact point 6,7 of the semiconducting layer 2.

In the second variant shown in the centre of FIG. 3 an electrically conductive connection 11 is achieved between the structured electrically conductive layer 10 and the semiconducting layer 2 through a bridge 27 punched out of the structured layer 10, which bridge is pressed onto a first or second contact point 6, 7 of the semiconducting layer 2 and joined in an electrically conductive way via ultrasonic welding. In the second variant, therefore, the hole 19 consists of two apertures in the shape of circular sections.

The embodiment shown in FIG. 3 on the right, an electric connection is achieved, in that the structured electrically conductive layer 10 is pressed through the first hole 9 onto a first or second contact point 6, 7 of the semiconducting layer 2, for example, by using a appropriately shaped sonotrode of an ultrasound welding device, and subsequently electrically connected by ultrasonic welding.

The electrically conductive connection 11 in the three variants shown in FIG. 3 is produced by ultrasonic welding. It is also conceivable, however, that between the structured electrically conductive layer 10 and the semiconducting layer 2 an electrically conductive adhesive is applied, which achieves the electric connection. In the first variant, the contact tape 12 can also be connected in an electrically conductive way to the structured electrically conductive layer 10 on one hand and with the semiconducting layer 2 on the other hand via an electrically conductive adhesive. Herein the electrically conductive adhesive could be applied to the contact points 6 and 7, for example, before or after the joining of the perforated foil 8 to the semiconducting layer 2.

FIG. 4 shows a cross-section through a solar cell according to an embodiment of the current invention. In FIG. 4, the surface of the solar cell facing away of the solar radiation is arranged on top and the surface facing toward the solar radiation is arranged on the bottom. Starting from the surface facing away from the solar radiation, first of all, there is arranged a protective layer (backsheet, for example from PVF like Tedlar®) 31, a structured electrically conductive layer 10, a perforated electrically non-conductive layer 8 with first holes 9, a semiconducting layer 2, a second single layer or multilayer foil 14, which comprises, for example, an antireflective layer and/or an ethylene-vinylacetate polymer foil as an additional protective layer, as well as a pane of glass 15.

In the embodiment of a solar cell according to the invention shown in FIG. 4, an electrically conductive connection 11 is achieved according to the second or third variant from FIG. 3, in that the structured electrically conductive layer 10 is joined to a first or second contact point 6, 7 on the semiconducting layer 2 through a first hole 9. The connection 11 was produced using ultrasonic welding or laser beam welding.

FIG. 5 shows a cross-section through a solar cell according to another embodiment of the present invention, in which the solder-free electric connection 11 is achieved through a contact tape 12. The layer composition is corresponding to the one shown in FIG. 4. The first variant from FIG. 1 is seen in a cross-section in FIG. 5 on the left. The solder-free electrically conductive connection 11 was produced in the first variant via ultrasonic welding or laser beam welding. In FIG. 5 on the right, a fifth variant of the solder-free electrically conductive connection 11 is shown, in which a contact tape 12 is connected in an electrically conductive way to the structured electrically conductive layer 10 as well as with a first or second contact point 6, 7 of the semiconducting layer using an electrically conductive adhesive.

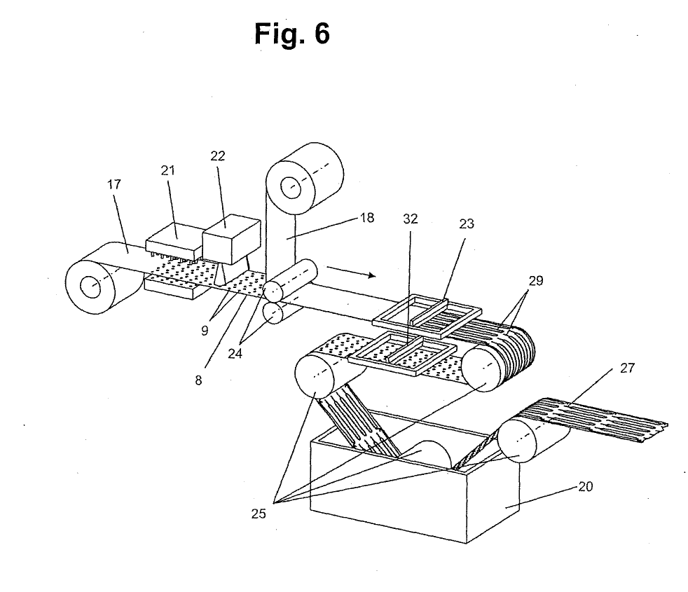

FIG. 6 shows a perspective view of a first embodiment of a method according to the invention to produce a contact foil. The arrow shows the direction of movement of the foils.

In this embodiment a single layer foil 17 is used as a single layer or multilayer foil. The single layer foil 17 entering from a supply reel is punched in a punching device 21 and subsequently coated with an adhesive in an adhesive coating device 22 on that surface of said foil, which is subsequently to be joined to an electrically conductive layer. After the coating with adhesive, the perforated foil 8, which is equipped with holes 9, is brought together with another metal foil as electrically conductive layer 18 from another reel. By means of laminating cylinders 24, a sound bond between both foils is produced. The surface of the metal foil 18, which surface is facing the multilayer perforated foil 8 is then provided with a covering layer 29 in certain places to be protected using a first screen printing device 23, which covering layer 29 has the purpose to protect the places of the electrically conductive metal foil 18, which places are to be protected from etching off in an etching bath 20. The foil laminate is then transported to a second screen printing device 32, in which the rear surface of the electrically conductive layer 18 is provided with a covering layer 29 over its entire surface. Subsequently, the foil laminate treated in this way arrives inside an etching bath 20, where the parts of the metal foil 18 not protected are etched off and only the desired conductive tracks of the structured electrically conductive layer 10 remain. The contact foil 27 thus yielded is transported on using transport cylinders, for example, into a cleaning bath not shown herein, in order to remove residuals from the etching bath 20 adhering to the contact foil 27 and/or to remove the covering layer 29.

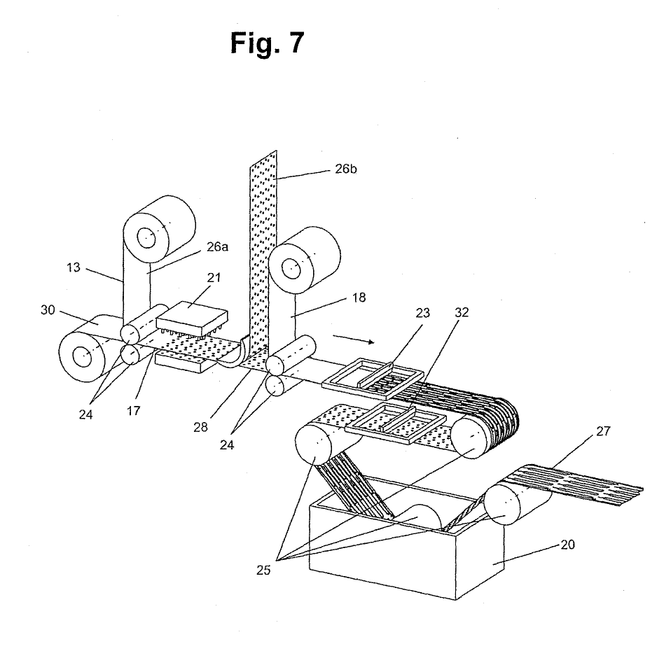

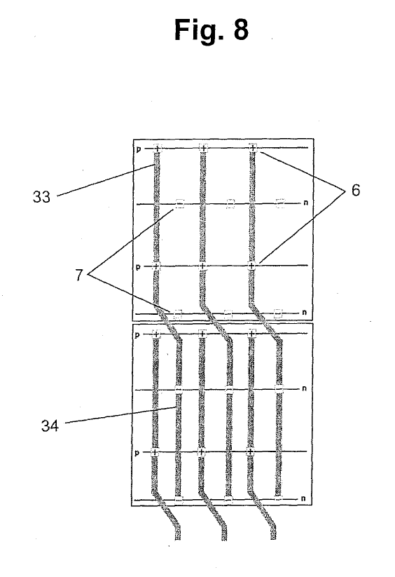

FIG. 7 shows a perspective view of a second embodiment for a method according to the invention to produce a contact foil.

In the second embodiment of the method according to the invention to produce a contact foil shown in FIG. 7, a double-sided self-adhesive insulating foil 13, which comprises a separating foil 26a on one side, is first laminated to a fusible foil 30. The laminating is supported by the first laminating cylinders 24. The single layer or multilayer foil thus yielded 17 consisting of one or several electrically non-conductive materials is subsequently punched in a punching device 21. Next, the punched separating foil 26b is pulled off towards the top, while the single layer or multilayer perforated foil 28 from an electrically non-conductive material is brought together with a metal foil from another reel as an electrically conductive layer 18. By using laminating cylinders 24, a sound bond between these two foils is produced. Subsequently, the surface of the metal foil 18, which surface is facing the multilayer perforated foil 28, is provided in places, which are to be protected from etching off with a covering layer 29 using a first screen printing device 23, which covering layer serves the purpose, to protect the places to be protected of the electrically conductive metal foil 18 from etching off in an etching bath 20. The foil laminate is then transported to a second screen printing device 32, in which the rear surface of the electrically conductive layer 18 is provided with a covering layer 29 over its entire surface. Subsequently, the foil laminate treated in this was arrives inside an etching bath 20, where the parts of the metal foil 18 not protected are etched off and only the desired conductive tracks of the structured electrically conductive layer 10 remain. The contact foil 27 thus yielded is transported using transport cylinders, for example, into a cleaning bath (immersion bath) not shown herein, in order to remove residuals from the etching bath 20 adhering to the contact foil 27 and/or to remove the covering layer 29.

FIG. 8 shows a typical interconnection variant in a solar module. Shown are two solar cells 1 with first contact points 6 with positive polarity and with second contact points 7 with negative polarity. The first contact points 6 are connected electrically conductively in the solar cell displayed on the left with a first contact finger 33 and the second contact points 7 with negative polarity in the solar cell displayed on the right are connected electrically conductively with a second contact finger 34. First contact finger 33 and second contact finger 34 are in turn connected to each other and thus produce an electric connection between the two solar cells. In an analogue fashion, those two solar cells are connected to other solar cells not shown in FIG. 8.

### REFERENCE LIST

1 solar cell
2 semiconducting layer
3 solar module
4 first surface of the semiconducting layer
5 second surface of the semiconducting layer
6 first contact points (positive polarity)
7 second contact points (negative polarity)
8 perforated foil from electrically non-conductive material
9 first holes (in insulating layer)
10 structured electrically conductive layer
11 electrically conductive connection
12 contact tape
13 double-sided self-adhesive insulating foil
14 “intermediate layer”
15 pane of glass
16 electrically conductive adhesive
17 first single layer or multilayer foil (insulating)
18 electrically conductive layer
19 second holes (in electrically conductive layer)
20 etching bath
21 perforating device
22 adhesive coating device
23 first screen printing device
24 laminating cylinders
25 transporting cylinders
26a separating foil
26b perforated separating foil
27 contact foil
28 perforated single layer or multilayer foil
29 covering layer
30 fusible layer
31 protective layer
32 second screen printing device
33 first contact finger
34 second contact finger

### SUMMARY

The invention concerns a solar cell 1 which comprises the following layers:
(a) a semiconducting layer 2 with a first surface 4 and a second surface 5, wherein on the first surface 4 there are a plurality of first contact points 6 and second contact points 7, which show opposing polarity;
(b) a first single layer or multilayer perforated foil 8,28, consisting of an electrically non-conductive material, said foil containing a plurality of first holes 9;
(c) a structured electrically conductive layer 10 on a surface of the perforated foil 8,28, which surface is facing away from the semiconducting layer 2;
   wherein the perforated foil 8,28 and the semiconducting layer 2 are positioned in such a way that at least a part of the first holes 9 and the first contact points 6 and the second contact points are facing each other, wherein at least a part of the first contact points 6 and the second contact points 7 are joined to the structured electrically conductive layer 10 via a solder-free electrically conductive connection 11. Furthermore, the invention concerns a solar module, which comprises a plurality of said solar cells, a method to produce said solar cell as well as a method to produce a contact foil.

1. Solar cell comprising the following layers:
(a) a semiconducting layer with a first surface and a second surface, wherein on the first surface there are a plurality of first contact points and second contact points, which show opposing polarity;
(b) a first single layer or multilayer perforated foil, consisting of an electrically non-conductive material, said foil containing a plurality of first holes;
(c) a structured electrically conductive layer on a surface of the perforated foil, which surface is facing away from the semiconducting layer;
wherein the perforated foil and the semiconducting layer are positioned in such a way that at least a part of the first holes and the first contact points and the second contact points are facing each other,
wherein at least a part of the first contact points and the second contact points are joined to the structured electrically conductive layer via a solder-free electrically conductive connection, and
wherein the solder-free electrically conductive connection comprises a contact tape between the part of the first and second contact points and the structured electrically conductive layer.

2. (canceled)

3. Solar cell according to claim 1 wherein the solder-free electrically conductive connection comprises an electrically conductive adhesive.

4. Solar cell according to claim 1 wherein the solder-free electrically conductive connection is obtainable by ultrasonic welding or laser beam welding.

5. Solar cell according to claim 4, wherein the solder-free electrically conductive connection is a direct connection between the part of the first and second contact points and the structured electrically conductive layer.

6. Solar module comprising a plurality of solar cells according to claim 1.

7. Method for producing a solar cell the solar cell comprising the following layers:
(a) a semiconducting layer with a first surface and a second surface, wherein on the first surface there are a plurality of first contact points and second contact points, which show opposing polarity;
(b) a first single layer or multilayer, perforated foil, consisting of an electrically non-conductive material, said foil containing a plurality of first holes;
(c) a structured electrically conductive layer on the surface of the perforated foil, which surface is facing away from the semiconducting layer;
wherein the perforated foil and the semiconducting layer are positioned in such a way that at least a part of the first holes and the first contact points and the second contact points are facing each other and wherein at least one part of the first and the second contact points are joined to the structured electrically conductive layer via a solder-free electrically conductive connection,
and wherein
(d) a first single layer or multilayer perforated foil, consisting of an electrically non-conductive material, said foil containing a plurality of first holes, is applied on a semiconducting layer, and an electrically conductive layer is applied to said perforated foil, wherein the perforated foil is applied on the semiconducting layer in such a way that at least a part of the first holes and the first contact points and the second contact points are facing each other;
(e) the electrically conductive layer undergoes structuring; and
(f) the structured electrically conductive layer thereby generated, is joined through the first holes to the first contact points and the second contact points via a solderless electrically conducting connection.

8. Method according to claim 7, wherein the structured electrically conductive layer is joined to the first contact points and the second contact points by ultrasonic welding or laser beam welding.

9. Method according to claim 7 wherein a first single layer or multilayer foil consisting of one or several electrically non-conductive materials is perforated by way of punching, thus yielding a plurality of first holes and the thereby generated first single layer or multilayer, perforated foil is laminated to an electrically conductive layer.

10. Method according to claim 7 wherein the structured electrically conductive layer is pressed through the first holes onto the first contact points and the second contact points and subsequently the structured electrically conductive layer is joined to the first contact points and the second contact points by ultrasonic welding.

11. Method according to claim 10, wherein the pressing of the structured electrically conductive layer onto the first contact points and the second contact points is carried out using an ultrasonic welding device.

12. Method according to claim 7 wherein the electrically conductive layer is provided with a plurality of second holes by punching in such way that the second holes are positioned on top of the first holes; a contact tape is applied between the part of the first contact points and the second contact points and the structured electrically conductive layer; and a solder-free electrically conductive connection is produced.

13. Method for producing a contact foil which comprises a structured electrically conductive layer and a first single layer or multilayer, perforated foil consisting of an electrically non-conductive material with a plurality of first holes, wherein (g) a first single layer or multilayer foil consisting of one or several electrically non-conductive materials is provided;
(h) a first single layer or multilayer foil is joined to an electrically conductive layer;
(i) a covering layer is applied to at least one portion of the electrically conductive layer;
(j) the parts of the electrically conductive layer not provided with the covering layer are removed in an etching bath, wherein before step (h) a plurality of first holes is created in at least the first single layer or multilayer foil by way of punching.

14. Method according to claim 13, wherein the first single layer or multilayer foil contains a double sided self-adhesive insulating foil, on one face of said foil is applied a protective layer and on the other face a separating foil.

15. Method according to claim 13, wherein the first single layer or multilayer foil is provided with an adhesive on the surface which is to be joined to an electrically conductive layer.

16. Method according to claim 8, wherein a first single layer or multilayer foil consisting of one or several electrically non-conductive materials is perforated by way of punching, thus yielding a plurality of first holes and the thereby generated first single layer or multilayer, perforated foil is laminated to an electrically conductive layer.

17. Method according to claim 8 wherein the structured electrically conductive layer is pressed through the first holes onto the first contact points and the second contact points and subsequently the structured electrically conductive layer is joined to the first contact points and the second contact points by ultrasonic welding.

18. Method according to claim 8 wherein the electrically conductive layer is provided with a plurality of second holes by punching in such way that the second holes are positioned on top of the first holes; a contact tape is applied between the part of the first contact points and the second contact points and the structured electrically conductive layer; and a solder-free electrically conductive connection is produced.
